(19) United States
(12) Patent Application Publication
(10) Pub. No.: US 2006/0270304 A1
(43) Pub. Date: Nov. 30, 2006

(54) Electro-optical panel, sealing member, electro-optical panel manufacturing method, self-emission panel, self-emission panel manufacturing method, and sealing member for use in self-emission panel

(75) Inventor: Toshiharu Aita, Yamagata (JP)

Correspondence Address: ARENT FOX PLLC, 1050 CONNECTICUT AVENUE, N.W., SUITE 400, WASHINGTON, DC, 20036, US

(73) Assignee: TOHOKU PIONEER CORPORATION

(21) Appl. No.: 11/411,934

(22) Filed: Apr. 27, 2006

(30) Foreign Application Priority Data
May 24, 2005 (JP) JP 2005-151298
Jun. 16, 2005 (JP) JP 2005-176631

(51) Int. Cl. H01J 9/26

(52) U.S. Cl. 445/25

(57) ABSTRACT

It is an object of the present invention to provide an improved structure having an adequate strength to satisfy a requirement of making a thin electro-optical panel. The electro-optical panel forms a sealing area having an electro-optical functional section between the support substrate and the sealing member. The support substrate has a lead-out area containing an area for forming lead-out wiring extending from the sealing area and for connecting or mounting the driving means (IC chip, flexible substrate and the like) to the lead-out wiring. The sealing member has protruding reinforcement sections protruding from the sealing area S on to the lead-out area. The support substrate and the sealing member are bonded together through an adhesive layer, thereby forming an adhesive area surrounding the sealing member. It is another object of the present invention to provide an improved process of producing a plurality of self-emission panels formed by cutting a mother panel into a plurality of unit panels, to prevent lead-out wiring portions from being wounded during the cutting process, thereby improving the yield of production. A further object of the invention is to improve the efficiency of inspection step, thereby improving the productivity of manufacturing process. A mother self-emission panel comprises a mother support substrate having formed thereon a plurality of self-emission sections, and a mother sealing member having arranged thereon a plurality of sealing sections corresponding to the plurality of self-emission sections. When the mother support substrate and the mother sealing member are bonded together, a plurality of sealing areas will be formed to seal the plurality of self-emission sections corresponding to the plurality of sealing sections. The mother support substrate has a plurality of lead-out areas having formed thereon a plurality of lead-out wiring portions extending from the plurality of self-emission sections to the outsides of the sealing areas. The mother sealing member has a plurality of hole processing portions for exposing the lead-out wiring portions.

### BACKGROUND OF THE INVENTION

The present invention relates to an electro-optical panel, a sealing member and a method of manufacturing the electro-optical panel.

The present application claims priority from Japanese Application No. 2005-151298, the disclosures of which are incorporated herein by reference.

Electro-optical panels represented by EL (Electroluminescent) display panel, PDP (Plasma Display Panel), FED (Field Emission Display) panel or liquid crystal display panel are usually adopted in various kinds of electronic apparatus, serving as a flat-panel display, an illumination member or the like. In particular, an organic EL panel can of course perform a color-displaying capable of obtaining a desired brightness efficiency at various colors RGB, and is characterized in that its drive voltage is as low as several to several tens of volts, provides a high visibility even when viewed from an inclined angle, and exhibits a high velocity response with respect to display changeover. Further, an organic EL panel is expected to be thinner so as to replace a liquid crystal display panel.

Such an electro-optical panel has a basic structure in which a sealing area is formed between mutually facing members and an electro-optical functioning section is formed in the sealing area. If an electro-optical panel is an organic EL panel, a self-emission section consisting of organic EL device(s) will be located within a sealing space formed by bonding together a flat substrate and a sealing member (such as a glass sealing member or a metal sealing cover). On the other hand, if an electro-optical panel is a PDP (Plasma Display Panel), an electric discharge space capable of light emission will be formed between a pair of mutually facing substrates. Further, if an electro-optical panel is a liquid crystal display panel, a liquid crystal sealing area will be formed between a pair of mutually facing substrates.

Regarding to the above-described electro-optical panels, at least one of each pair of mutually facing members forms a driving substrate, while a lead-out wiring extending from the above sealing area is formed in an edge portion of the driving substrate. The edge portion is so formed that it allows the connection between the lead-out wiring and driving means or the mounting of driving means. FIG. 1(a) is a plan view showing an example of a conventional technique mentioned above. As shown, the conventional structure comprises a substrate J1 and a sealing plate J2 for sealing organic EL device(s) formed on the substrate J1. Further, on an area of the substrate J1 where the sealing plate J2 is not disposed, there is formed part of a circuit for driving or controlling the organic EL device(s), with a circuit element J3 being COG (Chip on Glass) mounted thereon, as disclosed in Japanese Unexamined Patent Application Publication No. 2000-58255.

In the above-described conventional electro-optical panel, as shown in FIGS. 1(a) and 1(b) (FIG. 1(b) is a sectional view taken along J-J line in FIG. 1(a)), a support substrate (substrate J1) includes a lead-out area A in which a lead-out wiring extending from a sealing area is formed and driving means (the circuit element J3 or a flexible wiring board J4) is connected or mounted to the lead-out wiring, with the lead-out area A extending outwardly from one end of the sealing member (sealing plate J2). In particular, when adopting the COG shown in the drawing, a relatively large space is required to connect or mount driving means such as circuit elements or the like, so that the lead-out area A has to be made inevitably large.

In the above-described structure, once a load or an impact such as a force F acts on an outer end of the lead-out area A, a stress will be concentrated in an inner end position A₀ (boundary portion of the sealing member) of the lead-out area A. As a result, the lead-out area A will be supported only on one side thereof, causing a maximum bending moment with respect to the force F. On the other hand, an electro-optical panel is required to have a thin structure so as to reduce an internal space in the thickness direction when mounting electronic devices, resulting in a requirement that the support substrate be made as thin as possible. This, however, causes a problem in which the support substrate is easy to break at the inner end position A₀, and the breakage of support substrate becomes even worse if the support substrate is made still thinner.

On the other hand, as shown in FIG. 1(b), it is also possible to cover the lead-out area A with a reinforcing resin J5. However, once there is an external force which is equal to or larger than an adhesion strength combining together the adhesion resin J5 and the sealing member J2, the support substrate will be broken at the inner end position A₀, making it difficult to solve the aforementioned problem.

The present invention also relates to a self-emission panel, a method of manufacturing the self-emission panel, and a sealing member for use in the self-emission panel.

The present application also claims priority from Japanese Application No. 2005-176631, the disclosures of which are incorporated herein by reference.

Self-emission panels represented by EL (Electroluminescent) display panel, PDP (Plasma Display Panel), FED (Field Emission Display) panel are usually adopted in various kinds of electronic apparatus, serving as a flat-panel display, an illumination member or the like. In particular, an organic EL panel can of course perform a color-displaying capable of obtaining a desired brightness efficiency at various colors RGB, and is characterized in that its drive voltage is as low as several to several tens of volts, provides a high visibility even when viewed from an inclination, and exhibits a high velocity response with respect to display changeover. Further, a self-emission panel is expected to be thinner.

Such a self-emission panel has a basic structure in which a sealing area is formed between a support substrate and a sealing member, with a self-emission section formed in the sealing area. It is known that if a self-emission panel is an organic EL panel, when organic EL devices essential for forming the self-emission section are exposed to the outside atmosphere, its light emission performance will become deteriorated. Accordingly, after the self-emission section has been formed on the support substrate, the support substrate and the sealing member (such as a glass sealing member or a metal sealing cover) are bonded to each other, thereby covering the self-emission section within the sealing area.

In a process of manufacturing the above-mentioned self-emission panel, a high production efficiency can be obtained if a plurality of self-emission sections are formed on a mother support substrate, covered by a mother sealing member, followed by cutting and thus dividing the same into a plurality of self-emission panels.

FIGS. 2(a) to 2(c) are explanatory views showing a process of manufacturing the above-mentioned self-emission panels (which is disclosed in Japanese Unexamined Patent Application Publication No. 2005-78932). As shown in FIG. 2(a), a plurality of self-emission sections J10 are formed on a mother support substrate J101, with each self-emission section J10 connected to a lead-out wiring portion J11. Further, a mother sealing member J201 has formed thereon a plurality of moisture capturing material receiving portions J2a corresponding to a plurality of self-emission sections J10, with a moisture capturing material located in the center thereof. Moreover, the mother sealing member J201 (or the mother support substrate J101 has formed thereon a plurality of annular adhesive layer J21 each surrounding a self-emission section J10. In addition, another annular adhesive layer J22 is formed so that the large panel can be divided into a plurality of small panels. Afterwards, a further annular adhesive layer J23 is formed on the edge portion of the mother sealing member J201.

As shown in FIG. 2(b), the mother support substrate J101 and the mother sealing member J201 are bonded to each other through the adhesive layers J21, J22, and J23, thereby forming sealing areas containing the self-emission sections J10 on the inner side of the annular adhesive layer J21.

Then, after curing the adhesive layers J21, J22, and J23, the mother support substrate J101 and the mother sealing member J201 are cut into a plurality of small portions along the cutting lines C₁₀, C₁₁, and C₂ in a manner as shown in FIG. 2(b), thereby forming a plurality of self-emission panels J301.

According to the above-discussed conventional process of manufacturing self-emission panels, in a cutting process shown in FIG. 2(c), an edge portion J30e of a separated piece J30 will undesirably get into contact with the lead-out wiring portion J11 of a self-emission panel J301 and this will wound its lead-out wiring portion, causing a problem of wiring breakage in the lead-out wiring portion of the self-emission panel J301. In fact, such a trouble in the lead-out wiring portion usually occurs at the end of the above-mentioned manufacturing process, making unacceptable apiece of product corresponding to one panel, resulting in a waste of an amount of material supplied for making one panel in the manufacturing process. Therefore, a damage on a lead-out wiring portion during the cutting process makes it difficult to improve the yield of product and to reduce the manufacturing cost.

Moreover, after the self-emission sections J10 have been sealed, an inspection step is carried out to check the operating state of the self-emission sections J10. In such an inspection step, an inspection terminal has to be connected to each lead-out wiring portion J11 extending from a sealing area, so as to perform a lighting confirmation, a brightness measurement, a chromaticity measurement and the like. In prior art, since each lead-out wiring portion J11 is covered by the mother sealing member J201 before panel cutting process (as shown in FIG. 2(b)), the inspection step is carried out after an original large panel has been cut and divided into a plurality of small panels. However, after the panel cutting process, a plurality of separated self-emission panels J301 have to be picked up one by one, making extremely difficult an operation of connecting an inspection terminal to each lead-out wiring portion J11, hence requiring an increased operating time for the entire manufacturing process, thus making it impossible to ensure an increased productivity.

### SUMMARY OF THE INVENTION

The present invention is to solve the aforementioned problems and it is an object of the invention to provide a support structure having an adequate strength to meet the requirement of making a thin electro-optical panel, ensuring a structure capable of avoiding the stress concentration in the support substrate and thus rendering the substrate less breakable. In particular, the present invention is to provide a reinforcing structure effective for reinforcing a support substrate adopting COG structure.

Further, the present invention is to provide an improved process of producing a plurality of self-emission panels formed by cutting a large panel into a plurality of small portions, so as to prevent the lead-out wiring portions from being wounded during the cutting process, thereby improving the yield of production. Another object of the present invention is also to provide an improved process of producing a plurality of self-emission panels formed by cutting a large panel into a plurality of small portions, so as to improve the efficiency of an inspection step, thereby improving the productivity of manufacturing process.

In order to achieve the above objects, the present invention is characterized by at least the following aspects.

In one aspect of the present invention, there is provided an electro-optical panel including a sealing area having an electro-optical functional section between a pair of mutually facing members. This electro-optical panel is characterized in that one of the mutually facing members comprises a support substrate having a lead-out area containing an area for forming lead-out wiring extending from the sealing area and for connecting or mounting drive means to the lead-out wiring, the other of the mutually facing members has protruding reinforcement section(s) protruding from the sealing area on to the lead-out area.

In another aspect of the present invention, there is provided a sealing member forming a sealing area having an electro-optical functional section between the sealing member and a support substrate. This sealing member is characterized in that it has protruding reinforcement section(s) extending from the sealing area, and that the protruding reinforcement section(s) are formed on the support substrate and arranged in a lead-out area containing an area for forming lead-out wiring extending from the sealing area and for connecting or mounting the drive means to the lead-out wiring.

In a further aspect of the present invention, there is provided a method of manufacturing an electro-optical panel including a sealing area having an electro-optical functional section between a pair of mutually facing members. In this electro-optical panel, one of the mutually facing members comprises a support substrate having a lead-out area containing an area for forming lead-out wiring extending from the sealing area and for connecting or mounting drive means to the lead-out wiring, the other of the mutually facing members has protruding reinforcement section(s) protruding from the sealing area on to the lead-out area. The method of the invention is characterized in that an adhesive layer surrounding the sealing area is formed on one or both of the mutually facing members, and the pair of said mutually facing members are bonded together through the adhesive layer.

In one more aspect of the present invention, there is provided a self-emission panel in which a self-emission section is formed on a support substrate and disposed within a sealing area formed by bonding together the support substrate and a sealing member, a lead-out wiring portion extending from the self-emission section to the outside of the sealing area is formed on a lead-out area in an edge of the support substrate. In particular, the sealing member's edge facing the lead-out wiring portion is a hole processing edge formed before the support substrate and the sealing member are bonded together.

In one more aspect of the present invention, there is provided a self-emission panel comprising: a mother support substrate having formed thereon a plurality of self-emission sections; a mother sealing member having arranged thereon a plurality of sealing sections corresponding to the plurality of self-emission sections, and sealing areas formed by bonding together the mother support substrate and the mother sealing member for sealing the plurality of self-emission sections, with the plurality of self-emission sections corresponding to the plurality of sealing sections. In particular, the mother support substrate includes lead-out areas having formed thereon lead-out wiring portions extending from the plurality of self-emission sections to the outsides of the sealing areas, the mother sealing member has hole processing portions for exposing the lead-out wiring portions.

In one more aspect of the present invention, there is provided a method of manufacturing self-emission panels, the method comprising the steps of: forming a plurality of self-emission sections on a mother support substrate; forming on a mother sealing member hole processing portions corresponding to lead-out wiring portions of the plurality of self-emission sections; bonding together the mother support substrate and the mother sealing member to expose the lead-out wiring portions from the hole processing portions, and sealing the plurality of self-emission sections within sealing areas corresponding to sealing sections of the mother sealing member; examining the plurality of self-emission sections by connecting inspection terminals to the lead-out wiring portions exposed from the hole processing portions; cutting and dividing the mother support substrate and the mother sealing member into unit panels having the sealing areas and the lead-out wiring portions.

In one more aspect of the present invention, there is provided a self-emission panel sealing member for sealing a plurality of self-emission sections formed on a mother support substrate by being bonded to the mother support substrate. In particular, the sealing member has a plurality of sealing sections corresponding to the plurality of self-emission sections, and a plurality of hole processing portions corresponding to lead-out wiring portions of the plurality of self-emission sections.

### BRIEF DESCRIPTION OF THE DRAWINGS

These and other objects and advantages of the present invention will become clear from the following description with reference to the accompanying drawings, wherein:

FIGS. 1(a) and 1(b) are explanatory views showing a prior art;

FIGS. 2(a) to 2(c) are explanatory views showing another prior art;

FIGS. 3(a) and 3(b) are explanatory views showing an electro-optical panel according to one embodiment of the present invention (FIG. 3(a) is a plan view and FIG. 3(b) is a side view);

FIGS. 4(a) and 4(b) are explanatory views showing an electro-optical panel according to another embodiment of the present invention;

FIGS. 5(a) and 5(b) are explanatory views showing an electro-optical panel according to a further embodiment of the present invention;

FIG. 6 is an explanatory view showing an electro-optical panel according to one more embodiment of the present invention;

FIGS. 7(a) and 7(b) are explanatory views showing sealing members according to one embodiment of the present invention (FIG. 7(a) is a plan view and FIG. 7(b) is an X-X sectional view;

FIG. 8 is an explanatory view showing an organic EL panel which serves as an example of an electro-optical panel according to one embodiment of the present invention;

FIGS. 9(a) and 9(b) are explanatory views showing a self-emission panel formed according to an embodiment of the present invention (FIG. 9(a) is a perspective view and FIG. 9(b) is an X-X sectional view);

FIGS. 10(a) and 10(b) are explanatory plan views showing a condition in which a support substrate and a sealing member (which are in fact a mother support substrate and a mother sealing member) have not been bonded together, according to an embodiment of the present invention;

FIG. 11 is an explanatory sectional view showing a self-emission panel (which is in fact a mother self-emission panel) according to an embodiment of the present invention;

FIGS. 12(a) and 12(b) are explanatory views showing the cutting and dividing of a mother self-emission panel, according to an embodiment of the present invention;

FIGS. 13(a) and 13(b) show another embodiment of a mother self-emission panel (FIG. 13(a) is a sectional view showing a mother self-emission panel, FIG. 13(b) is a sectional view showing that the mother self-emission panel has been cut into a plurality of small portions);

FIG. 14 is a block diagram showing a process of manufacturing self-emission panels according to an embodiment of the present invention;

FIGS. 15(a) and 15(b) are explanatory views showing a self-emission panel formed according to another embodiment of the present invention (FIG. 15(a) is a perspective view and FIG. 15(b) is an X-X sectional view);

FIGS. 16(a) and 16(b) are explanatory views showing a self-emission panel according to another embodiment of the present invention (FIG. 16(a) is a perspective view and FIG. 16(b) is an X-X sectional view); and

FIG. 17 is an explanatory view showing the structure of an organic El panel which serves as an example of a self-emission panel according to an embodiment of the present invention.

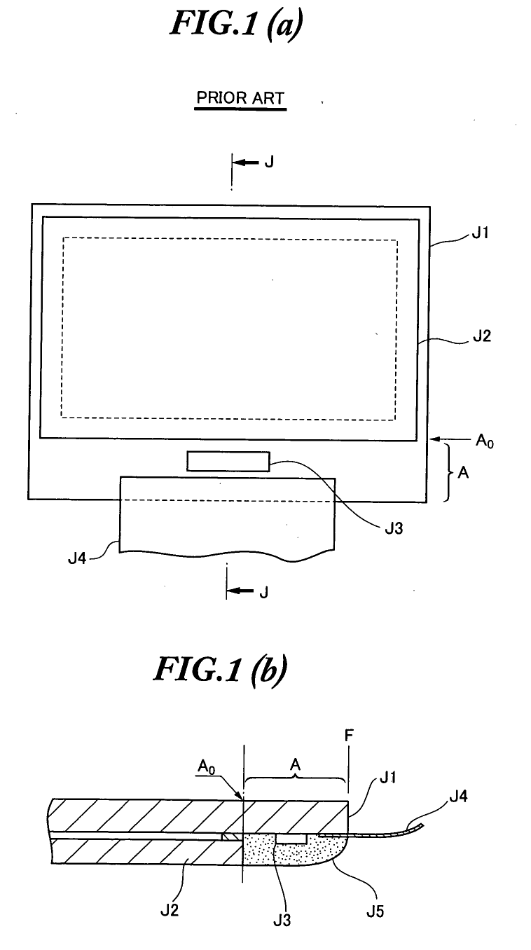

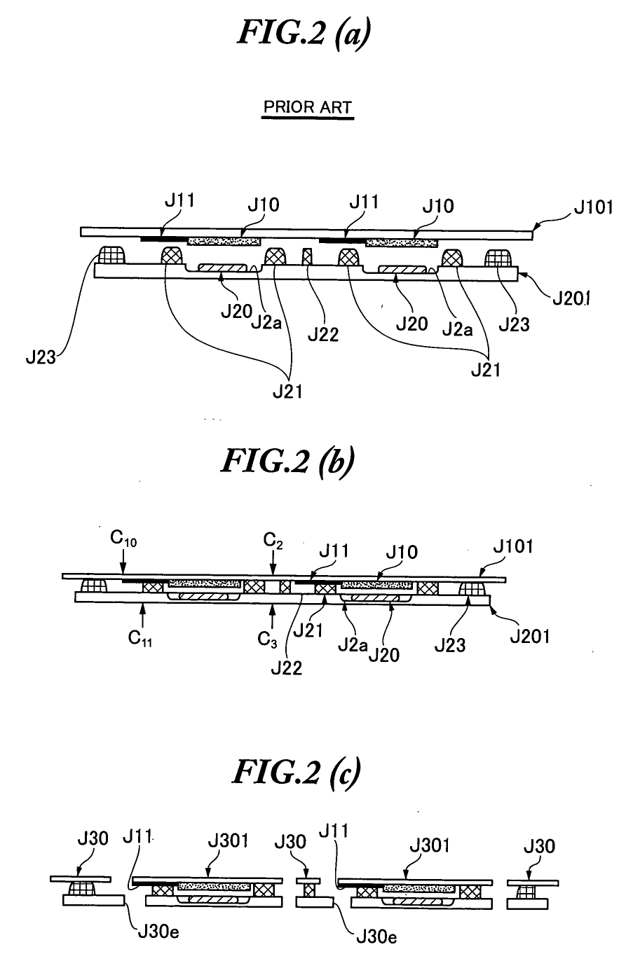

### DETAILED DESCRIPTION OF THE PREFERRED EMBODIMENTS

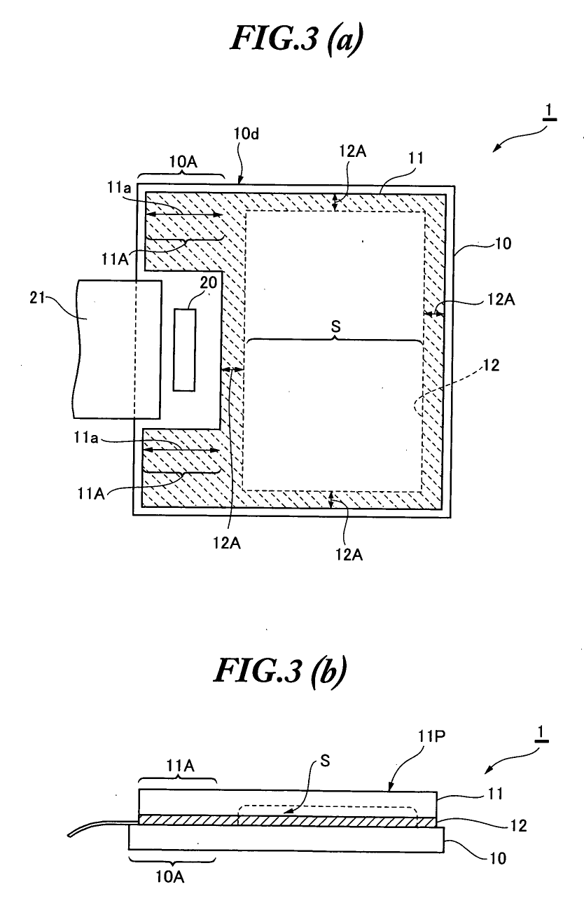

Hereafter, preferred embodiments of the present invention will be described with reference to the accompanying drawings. FIGS. 3(a) and 3(b) are explanatory views showing an electro-optical panel formed according to one embodiment of the present invention (FIG. 3(a) is a plan view and FIG. 3(b) is a side view). As shown, the electro-optical panel 1 has a basic structure in which a sealing area S including an electro-optical functional section is formed between a pair of mutually facing members. Here, so-called mutually facing members may include a support substrate 10 and a sealing member 11 which will be explained later, or a pair of mutually facing flat support substrates.

Here, one of a pair of mutually facing members comprises a support substrate 10 which includes a lead-out area 10A containing an area provided with a lead-out wiring (not shown) extending from the sealing area S and connecting or mounting the driving means (such as IC chip 20 and flexible substrate 21 or the like) to the lead-out wiring.

On the other hand, the other of a pair of mutually facing members is a sealing member 11 which includes protruding reinforcement sections 11A extending from the sealing area S on to the lead-out area 10A.

At this time, if the mutually facing surfaces of a pair of mutually facing members are in flat condition (such as the support substrate 10 and the sealing member 11), the sealing area S means an area formed between the mutually facing members through an interval keeping member such as a spacer. On the other hand, if the support substrate 10 or the sealing member 11 has a concave portion on its surface, the sealing area S means an area formed by the concave portion. Here, the pair of mutually facing members are bonded together through an adhesive layer 12, thereby forming an annular adhesion area 12A along the edge of the sealing member 11.

In the electro-optical panel 1 formed according to this embodiment of the present invention, with respect to the support substrate 10 having the lead-out area 10A, the sealing member 11 has protruding reinforcement sections 11A extending from the sealing area S on to the lead-out area 10A. In this way, it is possible for the lead-out area 10A to avoid a load or an impact which would otherwise act only on the lead-out area 10A, and it is also possible to disperse a stress concentration at an easily breakable position 10d (corresponding to the base of the protruding reinforcement sections 11A) on the support substrate 10, thereby improving the strength of the electro-optical panel 1.

On the other hand, the sealing member 11, which serves as the other of a pair of mutually facing members, forms a support plane 11P containing the sealing area S and the protruding reinforcement sections 11A. In fact, such a support plane 11P provides the following advantages. Namely, even when the other of a pair of mutually facing members, which is the sealing member 11, comes into contact with a support object, a support reaction force will act on the lead-out area 10A of the support substrate 10, thereby enabling the lead-out area 10A of the support substrate 10 to avoid a one-side force. In this way, it is possible to prevent a breakage in the aforementioned easily breakable position 10d.

Moreover, the protruding reinforcement sections 11A are formed on the lead-out area 10A except those areas for connecting or mounting the driving means (such as IC chip 20 and flexible substrate 21). In this way, even after a pair of mutually facing members are bonded together, it is still possible to connect or mount the driving means. Therefore, it is possible to form the protruding reinforcement sections 11A without unfavorably affecting the connecting or mounting position of the driving means.

Further, the protruding reinforcement sections 11A are bonded and thus fixed on the lead-out area 10A. Namely, an adhesive layer is formed between the protruding reinforcement sections 11A and the lead-out area 10A. The adhesion of such protruding reinforcement sections 11A does not affect the sealing performance of the sealing area S and it is possible to obtain certain reinforcing effect even if the protruding reinforcement sections 11A are not bonded thereto. Nevertheless, a stronger reinforcing effect can be obtained if the protruding reinforcement sections 11A are bonded thereto.

The embodiment illustrated in FIGS. 3(a) and 3(b) shows that there are a plurality of such protruding reinforcement sections 11A arranged in a plurality of positions along one side of the sealing member 11, with the protruding lengths 11a of the respective protruding reinforcement sections 11A being equal to one another. According to this embodiment, since the protruding reinforcement sections 11A are formed in a plurality of positions (two positions) which are not contained in the areas of the lead-out area 10A in which the driving means are connected or mounted, it is possible to more exactly reinforce the lead-out area 10A of the support substrate 10. Further, since the protruding length 11a of each protruding reinforcement section 11A can be made maximum in response to the width of the lead-out area 10A, it is also possible to more exactly reinforce the lead-out area 10A of the support substrate 10.

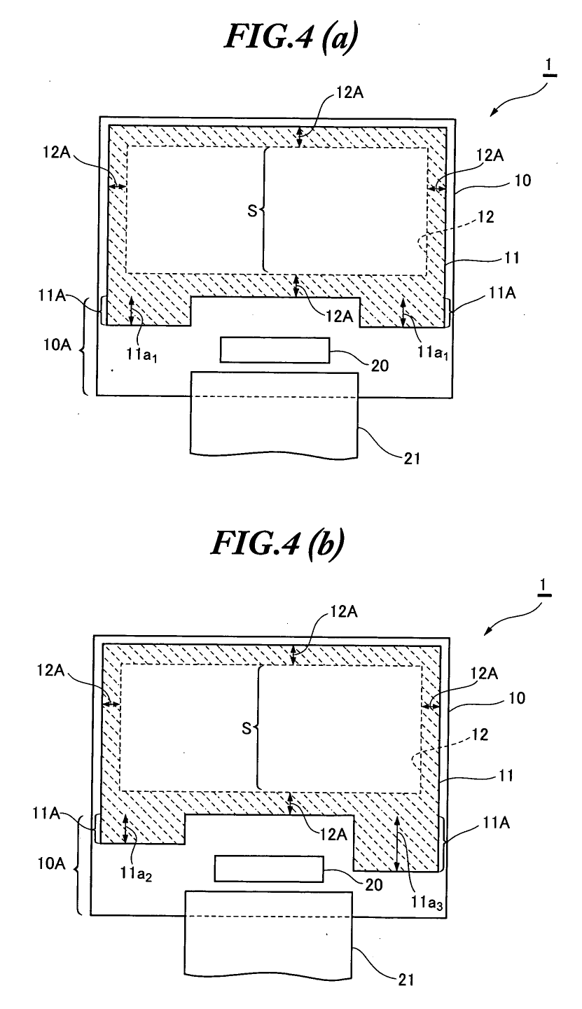

FIGS. 4(a)-6 show some modified embodiments of the electro-optical panel 1 formed according to the above-described embodiment of the present invention (in FIGS. 4(a)-6 the same elements as those in FIGS. 3(a) and 3(b) are represented by the same reference numerals and the same description will be omitted to some extent).

An embodiment shown in FIGS. 4(a) and 4(b) represents an example in which the protruding length of each protruding reinforcement section 11A has been set relatively short with respect to the width of the lead-out area 10A. As shown in FIG. 4(a), the protruding lengths 11a₁ of the protruding reinforcement sections 11A formed on both sides of the driving means (IC chip 20, flexible substrate 21 and the like) are equal to each other, and the protruding length 11a₁ of each protruding reinforcement section is short with respect to the width of the lead-out area 10A. At this time, it is possible to ensure, along an entire one side of the lead-out area 10A, an attachment area for attaching the IC chip 20 and a pressure-bonding area for pressure-bonding the flexible substrate 21, thus effectively enabling an operation for connecting or mounting the driving means.

Furthermore, this example shows that it is possible to protect an easily breakable portion of the lead-out area 10A by virtue of the protruding reinforcement sections 11A and also shows that since the width of the lead-out area 10A exposed from the edge of the protruding reinforcement sections 11A is shorter as compared with a case in which there is no protruding reinforcement section 11A, it is possible to alleviate to some extent a maximum bending moment acting on the exposed lead-out area 10A. In addition, it is also possible to solve a problem of stress concentration.

An example illustrated in FIG. 4(b) shows that the protruding lengths 11a₂ and 11a₃ of the protruding reinforcement sections 11A provided in a plurality of positions are different from each other. In fact, although the protruding lengths 11a₂ and 11a₃ are different from each other, it is still possible to obtain the same effect as obtainable in the example shown in FIG. 4(a).

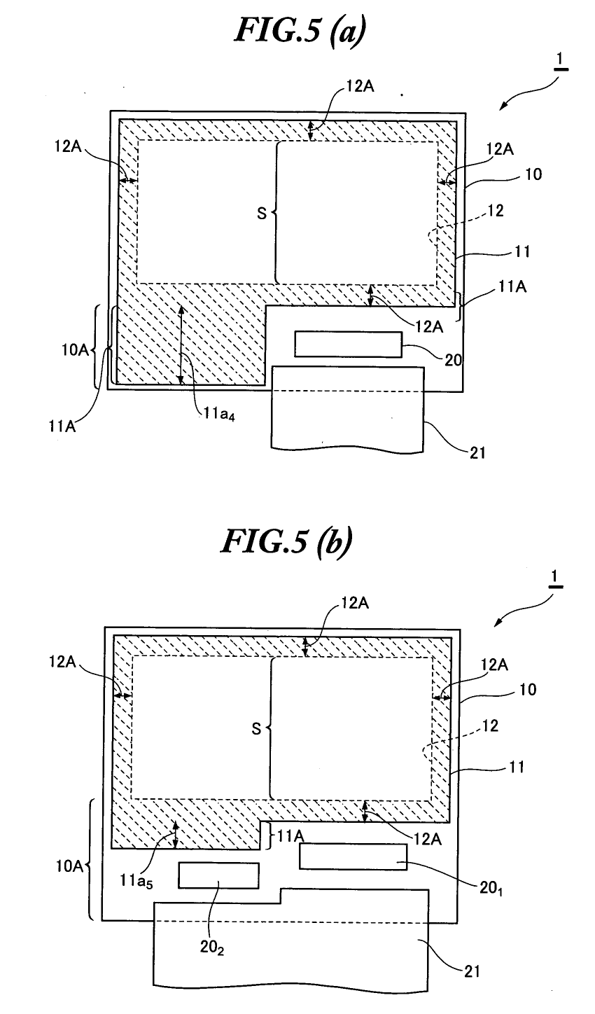

An embodiment illustrated in FIGS. 5(a) and 5(b) shows that only one position on one side of the lead-out area 10A is provided with a protruding reinforcement section 1A. As shown in FIG. 5(a), when the connecting or mounting position of the driving means (IC chip 20, flexible substrate 21 and the like) is located on the left or right side of the lead-out area 10A, an unused space on the opposite side can be used to provide another protruding reinforcement section 11A.

At this time, as shown in FIG. 5(a), the overhang length 11a₄ of the protruding reinforcement section 11A may have the same width as the lead-out area 10A. Alternatively, as show in FIG. 5(b), it is possible to form a shorter protruding length 11a₅ in a manner such that a free space is formed at an edge portion of the lead-out area 10A. Upon forming the structure shown in FIG. 5(b), it is possible to use some free spaces to arrange a plurality of IC chips 20, and 202, thereby ensuring several different types of arrangement for connecting or mounting the driving means. Of course, this embodiment provides the same reinforcing effect as the foregoing embodiments.

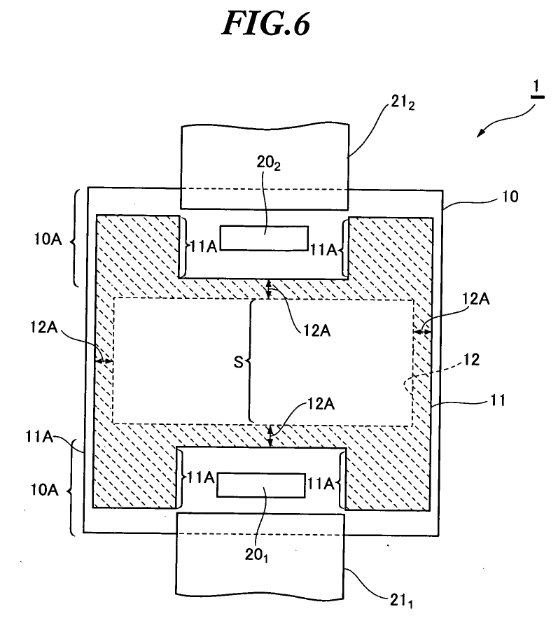

In an embodiment illustrated in FIG. 6, lead-out areas 10A and protruding reinforcement sections 11A like those shown in FIG. 3 are provided along two mutually facing lines of the support substrate 10 and the sealing member 11, thereby making it possible to attach the driving means (IC chips 201, 202 and flexible substrates 211, 212). In this way, an arrangement having a plurality of lead-out areas 10A on a plurality of sides of the support substrate 10 can provide a reinforcing effect using the same structure as described above.

In each of the above-described embodiments, one or both of each pair of mutually facing members (such as the support substrate 10 and the sealing member 11) is made of transparent material and it is possible to effect a light emission from the transparent material side. Therefore, if display apparatus is to be fabricated, it is possible to form one-side display by using a transparent material to form one side of the display, or to form double-sided display by using a transparent material to form both sides of the display. On the other hand, if an electro-optical functional section within the sealing area S is to be formed by organic EL device(s) formed on the support substrate 10, it is possible to form a bottom-emission type display in which the support substrate 10 is made of a transparent material and the light emission is effected from the support substrate side, and it is also possible to form a top-emission type display in which the sealing member is made of a transparent material and the light emission is effected from the sealing member side.

Further, upon paying attention to the sealing member 11, it will be found that the sealing member 11 has the following features. Namely, the sealing member 11 is formed with a sealing area S having an electro-optical functional section located between the sealing member 11 and the support substrate 10. In detail, the sealing member 11 has protruding reinforcement sections 11A protruding from the sealing area S. In fact, such protruding reinforcement sections 11A are located above the support substrate 10 and so formed that they are arranged on the lead-out area 10A containing an area for forming the lead-out wiring extending from the sealing area S and for connecting or mounting the driving means (IC chip 20, flexible substrate 21 and the like) to the lead-out wiring. On the other hand, as far as shape is concerned, the sealing member 11 is formed with notches which are adjacent to the protruding reinforcement sections 1A and open an area for connecting or mounting the driving means.

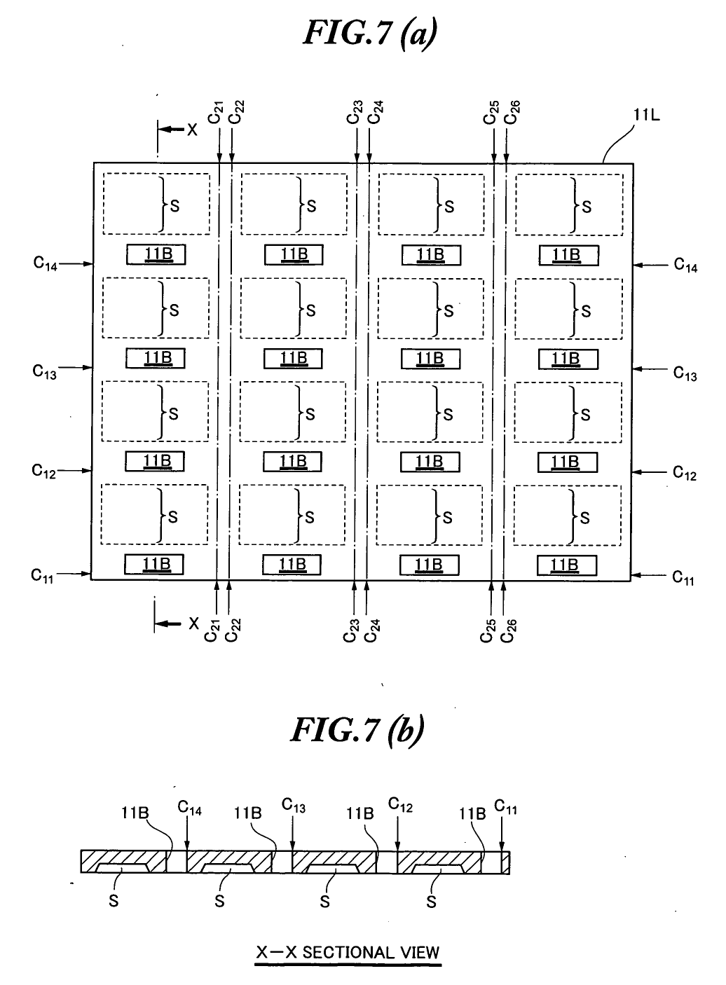

In order to efficiently form a plurality of sealing members 11 each having the above-described configuration, it is preferable to adopt an arrangement shown in FIGS. 7(a) and 7(b). Here, FIG. 7(a) is a plan view and FIG. 7(b) is an X-X sectional view. Namely, a plurality of sealing members 11 are formed by cutting one-piece plate 11L (forming a plurality of sealing areas S) into a plurality of sealing members, while a plurality of notches may be formed by virtue of openings 11B formed on such one piece plate 11L.

In this embodiment as illustrated, one-piece plate 11L has a plurality of openings 11B formed thereon in advance, and the plate 11L itself is cut along cutting lines C₁₁-C₁₄, and C₂₁-C₂₆ so as to form a plurality of sealing members 11. At this time, the openings 11B can be formed by masking process such as sandblasting, and it is possible to simultaneously form a plurality of such openings. Besides, recess portions corresponding to a plurality of sealing areas S can also be formed by virtue of masking process such as sandblasting.

Further, in this embodiment, the cutting lines C₁₁-C₁₄ are straight lines in alignment with the bottom lines of rectangular openings 11B, and a cutting process along these cutting lines makes it possible to form a plurality of U-shaped notches in a simple step, while protruding reinforcement sections 11A are formed on both the left and right sides of each notch.

Using the above-described sealing member manufacturing process, it is possible to produce, with a high productivity, a plurality of sealing members 11 each capable of reinforcing a support substrate 10 having a lead-out area 10A.

In the following, description will be given to explain an electro-optical panel manufacturing method according to one embodiment of the present invention. In detail, the method comprises forming an adhesive layer 12 surrounding a sealing area on one or both of a pair of mutually facing members (a support substrate 10 and a sealing member 11), and bonding together the pair of mutually facing members by virtue of the adhesive layer 12. Here, the adhesive layer 12 is formed on one or both of the support substrate 10 and the sealing member 11 by applying an adhesive using a dispenser or using one of any other various kinds of printing methods. Then, the pair of mutually facing members are bonded together in a desired atmosphere (an inert gas atmosphere or a vacuum gas atmosphere), followed by performing an adhesive curing treatment.

According to this manufacturing method, a sealing member 11 on which protruding reinforcement sections 11A have been formed in advance is bonded to a support substrate 10. In this way, the sealing member 11 can be processed in advance at a step not involved in the main manufacturing line, thereby making it possible to manufacture the sealing members without adding any additional step for processing the sealing members in the main manufacturing line. Moreover, if an adhesive layer is formed also on protruding reinforcement sections 11A when forming the adhesive layer 12 before bonding together the support substrate and the sealing member, the protruding reinforcement sections 11A can be bonded and thus fixed on the lead-out area 10A upon bonding together the support substrate and the sealing member for forming the sealing area S.

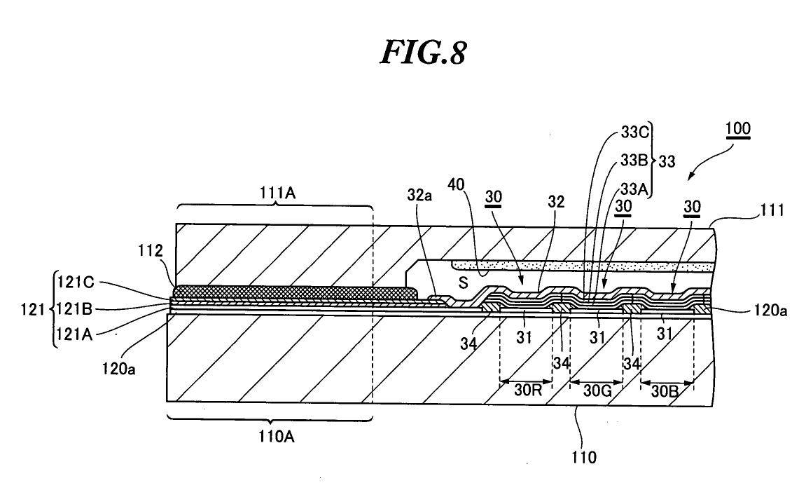

In the following, with reference to FIG. 8, description will be given to explain an organic EL panel serving as an example of the foregoing electro-optical panel 1.

As shown, an organic EL panel 100 is formed by interposing an organic layer 33 containing an organic luminescent layer between first electrodes 31 on one hand and second electrodes 32 on the other, thereby forming a plurality of organic EL devices 30 on the support substrate 110. In an example shown in FIG. 7, a silicone coating layer 120a is formed on the support substrate 110, and a plurality of first electrodes 31 consisting of transparent electrode material such as ITO and serving as anodes are formed on the silicon coating layer 120a. Further, second electrodes 32 consisting of a metal such as Al and serving as cathodes are formed over the first electrodes 31, thereby forming a bottom emission type panel capable of emitting light from the support substrate 110 side. Moreover, the panel also contains an organic layer 33 including a positive hole transporting layer 33A, a luminescent layer 33B, and an electron transporting layer 33C. Then, the support substrate 110 and a sealing member 111 are bonded together through an adhesive layer 112, thereby forming a sealing area S, thus forming a display section (electro-optical functional section) consisting of organic EL devices 30 within the sealing area S.

A display section consisting of organic EL devices 30, as shown in an example of FIG. 8, is so formed that its first electrodes 31 are divided by insulating strips 34, thereby forming a plurality of unit display areas (30R, 30G, 30B) by virtue of the respective organic EL devices 30 located under the divided first electrodes 31. Further, desiccating means 40 is attached to the inner surface of the sealing member 111 forming the sealing area S, thereby preventing a deterioration of the organic EL devices which is possibly caused due to moisture.

Moreover, on the lead-out area 110A formed along the edge of the support substrate 110 there is formed a first electrode layer 121A using the same material and the same step as forming the first electrodes 31, which is separated from the first electrodes 31 by the insulating strips 34. Further, on the lead-out portion of the first electrode layer 21A there is formed a second electrode layer 21B forming a low-resistant wiring portion containing a silver alloy or the like. In addition, if necessary, a protection coating layer 121C consisting of IZO or the like is formed on the second electrode layer 21B. In this way, a lead-out wiring portion 121 can be formed which consists of the first electrode layer 121A, the second electrode layer 121B, and the protection coating 121C. Then, an edge portion 32a of each second electrode 32 is connected to the lead-out wiring portion 121 at edge portion of the sealing area S.

Here, although the lead-out wiring portion of each first electrode 31 is not shown in the drawing, such lead-out wiring portion can be formed by extending each first electrode 31 and leading the same out of the sealing area S. Actually, such lead-out wiring portion can also be formed into an electrode layer forming a low resistant wiring portion containing a silver alloy or the like in a manner similar to an example associated with the above-described second electrode 32.

Then, on the lead-out area 110A of the support substrate 110, a protruding reinforcement section 111A of the sealing member 111 is formed in a manner shown in FIGS. 3(a)-6. Further, in notch of the protruding reinforcement section 11A, lead-out wiring is exposed on to the lead-out area 110A, and driving means such as an IC chip and a flexible substrate are connected or mounted (not shown) to the lead-out wiring 121 in a manner shown in FIGS. 3(a)-6.

Next, description will be given in more detail to explain the details of the aforementioned organic EL panel 100.

a. Electrodes

Either the first electrodes 31 or the second electrodes 32 are set as cathode side, while the opposite side is set as anode side. The anode side is formed by a material having a higher work function than the cathode side, using a transparent conductive film which may be a metal film such as chromium (Cr), molybdenum (Mo), nickel (nickel), and platinum (Pt), or a metal oxide film such as ITO and IZO. In contrast, the cathode side is formed by a material having a lower work function than the anode side, using a metal having a low work function, which may be an alkali metal (such as Li, Na, K, Rb, and Cs), an alkaline earth metal (such as Be, Mg, Ca, Sr, and Ba), a rare earth metal, a compound or an alloy containing two or more of the above elements, or an amorphous semiconductor such as a doped polyaniline and a doped polyphenylene vinylene, or an oxide such as Cr₂O₃, NiO, and Mn₂O₅. Moreover, when the first electrodes 31 and the second electrodes 32 are all formed by transparent materials, it is allowed to provide a reflection film on one electrode side opposite to the light emission side.

The lead-out wiring portion (the lead-out wiring portion 121 and the lead-out wiring portion of the first electrodes 31, as shown in the figure) are connected with drive circuit parts driving the organic EL panel 100 or connected with a flexible wiring board. However, it is preferable for these lead-out wiring portions to be formed as having a low resistance as possible. Namely, the lead-out wiring portions can be formed by laminating low resistant metal electrode layers which may be Ag-alloy, Cr, Al, or the like. Alternatively, they may be formed by single one electrode of low resistant metal.

b. Organic Layer

Although the organic layer 33 comprises one or more layers of organic compound materials including at least one organic luminescent layer, its laminated structure can be in any desired arrangement. Usually, in the case of a low molecule organic EL material, as shown in FIG. 8, there is a laminated structure including, from the anode side towards the cathode side, a hole transporting layer 33A, a luminescent layer 33B, and an electron transporting layer 33C. Each of the hole transporting layer 33A, the luminescent layer 33B, and the electron transporting layer 33C can be in a single-layer or a multi-layered structure. Moreover, it is also possible to dispense with the hole transporting layer 33A and/or the electron transporting layer 33C. On the other hand, if necessary, it is allowed to insert other organic layers including a hole injection layer, and an electron injection layer. Here, the hole transporting layer 33A, the luminescent layer 33B, and the electron transporting layer 33C can be formed by any conventional materials (it is allowed to use either a high molecular material or a low molecular material).

Regarding to a luminescent material for forming the luminescent layer 33B, it is allowed to make use of a luminescence (fluorescence) obtained when the material returns from a singlet excited state to a base state or a luminescence (phosphorescence) obtained when it returns from a triplet excited state to a base state.

c. Sealing Member

In the organic EL panel 100, the covering member for tightly covering organic EL devices 30 may be a plate-like member or container-like member made of metal, glass, or plastic. Here, the sealing cover may be a piece of material having a recess portion (a one-step recess or a two-step recess) formed by pressing, etching, or blasting. Alternatively, the sealing cover may be formed by using a flat glass plate capable of forming a sealing area S between the flat glass plate and the support substrate 110 by virtue of a spacer made of glass (or plastic).

d. Adhesive Agent

An adhesive agent forming the adhesive layer 112 may be a thermal-setting type, a chemical-setting type (2-liquid mixture), or a light (ultraviolet) setting type, which can be formed by an acryl resin, an epoxy resin, a polyester, a polyolefine. Particularly, it is preferable to use an ultraviolet-setting epoxy resin adhesive agent which is quick to solidify without a heating treatment.

e. Desiccating Means

Desiccating means 40 may be a physical desiccating agent such as zeolite, silica gel, carbon, and carbon nanotube; a chemical desiccating agent such as alkali metal oxide, metal halogenide, peroxide chlorine; a desiccating-agent formed by dissolving an organic metallic complex in a petroleum system solvent such as toluene, xylene, an aliphatic organic solvent and the like; and a desiccating agent formed by dispersing desiccating particles in a transparent binder such as polyethylene, polyisoprene, polyvinyl thinnate.

f. Various Types of Organic EL Panels

The organic EL panel 100 of the present invention can have various types without departing from the scope of the invention. For example, the light emission type of organic EL devices 30 can be bottom emission type which emit light from the substrate 110 side, or top emission type which emit light from the sealing member 111 side (at this time, it is necessary for the sealing member 111 to be made of a transparent material and to dispose the desiccating means 40). Moreover, an organic EL display panel 100 may be a single color display or a multi-color display. In order to form a multi-color display, it is possible to adopt a discriminated painting method or a method in which a single color (white or blue) luminescent layer is combined with a color conversion layer formed by a color filter or a fluorescent material (CF manner, CCM manner), a photograph breeching method which realizes a multiple light emission by emitting an electromagnetic wave or the like to the light emission area of a single color luminescent layer, a SOLED (transparent Stacked OLED) method in which two or more colors of unit display areas are laminated to form one unit display area, or a laser transfer method in which low molecular organic material having different luminescent colors are deposited in advance on to different films and then transferred to one substrate by virtue of thermal transfer using a laser. Besides, although the accompanying drawings show only a passive driving manner, it is also possible to adopt an active driving manner by adopting TFT substrate serving as support substrate 110, forming thereon a flattening layer and further forming the first electrodes 31 on the flattening layer.

As described above, regarding the electro-optical panel and the manufacturing method thereof according to the above-discussed embodiments of the present invention, it is possible to provide an improved support structure having an adequate strength to satisfy a requirement of making a thin electro-optical panel, as well as an improved structure capable of preventing a stress concentration from occurring in the support substrate so that the support substrate is not easily breakable.

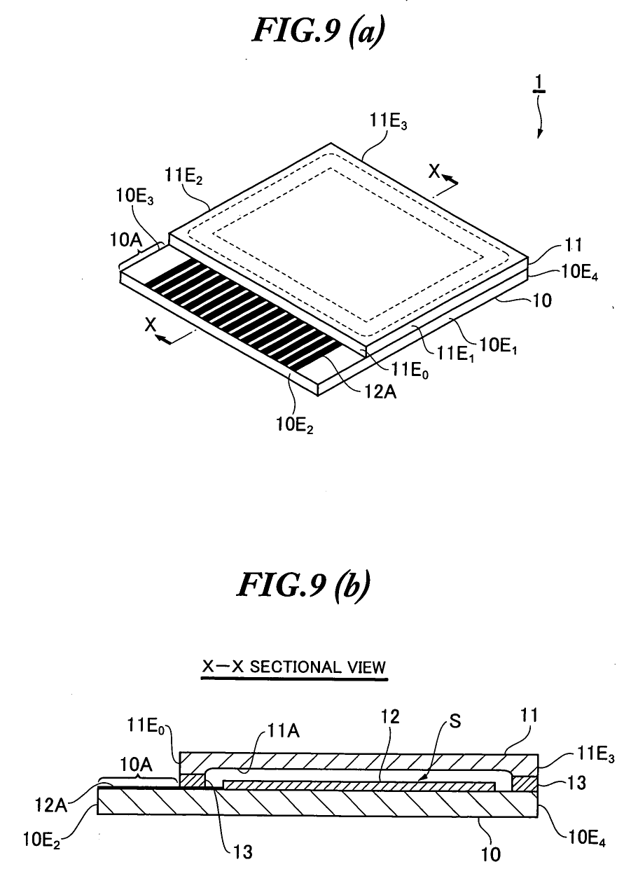

In the following, several more preferred embodiments of the present invention will be described with reference to the accompanying drawings. FIGS. 9(a) and 9(b) are explanatory views showing one embodiment of the present invention (FIG. 9(a) is a perspective view showing an outer appearance of a self-emission panel, and FIG. 9(b) is a cross sectional view taken along X-X line in FIG. 9(a)). As shown, the self-emission panel 1 is produced by forming a self-emission section 12 on a support substrate 10. Such a self-emission section 12 is disposed within a sealing area S formed by bonding together the support substrate 10 and a sealing member 11 through an adhesive layer 13. A lead-out wiring portion 12A extending from the self-emission section 12 to the outside of the sealing area S is formed on a lead-out area 10A of the support substrate 10.

Further, the self-emission panel 1 according to the present embodiment of the present invention includes a plurality of edges forming the periphery of the self-emission panel 1 consisting of the support substrate 10 and the sealing member 11 (the support substrate 10 includes edges 10E₁, 10E₂, 10E₃ and 10E₄, and the sealing member 11 includes edges 11E₁, 11E₂, and 11E₃). In fact, these edges are cutting edges which are formed after the support substrate 10 and the sealing member 11 have been bonded together. In detail, the edge 11E₀ facing the lead-out wiring portion 12A of the support substrate 10 is a hole processing edge shaped before the support substrate 10 and the sealing member 11 are bonded together. Here, so-called “cutting edge” is an edge formed during a cutting process, but also includes edges formed during various surface treatments after a cutting process. On the other hand, so-called “processing edge” is an edge formed by a processing (such as chipping, sandblasting, punching, and the like), also includes edges formed during various subsequent surface treatments.

Regarding the self-emission panel 1 formed according to the present embodiment, since the edge 11E₀ facing the lead-out wiring portion 12A of the support substrate 10 is a hole processing edge shaped before the support substrate 10 and the sealing member 11 are bonded together, any undesired effect possibly caused due to a cutting process after bonding will not affect the lead-out wiring portion 12A. In this way, cutting fragments will not get into contact with the lead-out wiring section 12A, thereby avoiding an adhesion of the cutting fragments to the surface of the lead-out wiring portion 12A, thus preventing any trouble which will possibly occur in the lead-out wiring portion 12A at the end of a panel manufacturing process.

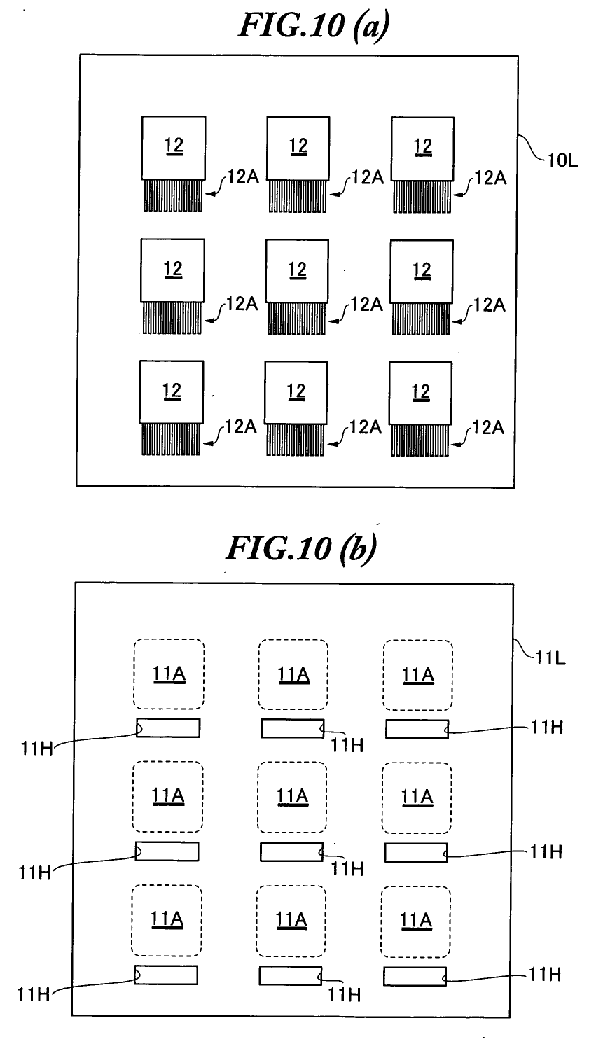

FIGS. 10(a) and 10(b) are explanatory views (plan views) showing a state in which a support substrate 10 and a sealing member 11 have not been bonded together (here, a support substrate 10 is a mother support substrate 10L, and a sealing member 11 is a mother sealing member 11L) As shown, a plurality of self-emission sections 12 are formed on the mother support substrate 10L, and arranged in a desired formation. Each self-emission section 12 has a lead-out wiring portion 12A formed therewith. In fact, the support substrate 10 mentioned earlier in this specification is one of a plurality of substrates formed by cutting the mother support substrate 10L into a plurality of small portions in accordance with every self-emission section 12.

On the other hand, a plurality of sealing sections 11A corresponding to the plurality of self-emission sections 12 formed on the mother support substrate 10L are arranged on the mother sealing member 11L. In fact, each of the sealing sections 11A can be a recess portion forming a sealing area S shown in FIG. 9(b). Alternatively, these sealing sections 11A can be on a plan surface containing a plurality of divided areas (at this time, a spacer member which may be an interval keeping fiber member capable of forming a plurality of sealing areas S is provided between the mother support substrate 10L and the mother sealing member 11L). Namely, the sealing member 11 mentioned earlier in this specification is one of a plurality of members formed by cutting the mother sealing member 11L into a plurality of small portions in accordance with every sealing section 11A.

Furthermore, the mother sealing member 11L has a plurality of hole processing portions 11H which are located in positions corresponding to the positions of the lead-out wiring portions 12A on the mother support substrate 10L when the mother sealing member 11L is bonded to the mother support substrate 10L. Namely, the edge 11E₀ (hole processing edge) of the sealing member 11 can be formed as part of the inner edge of the hole processing portion 11H.

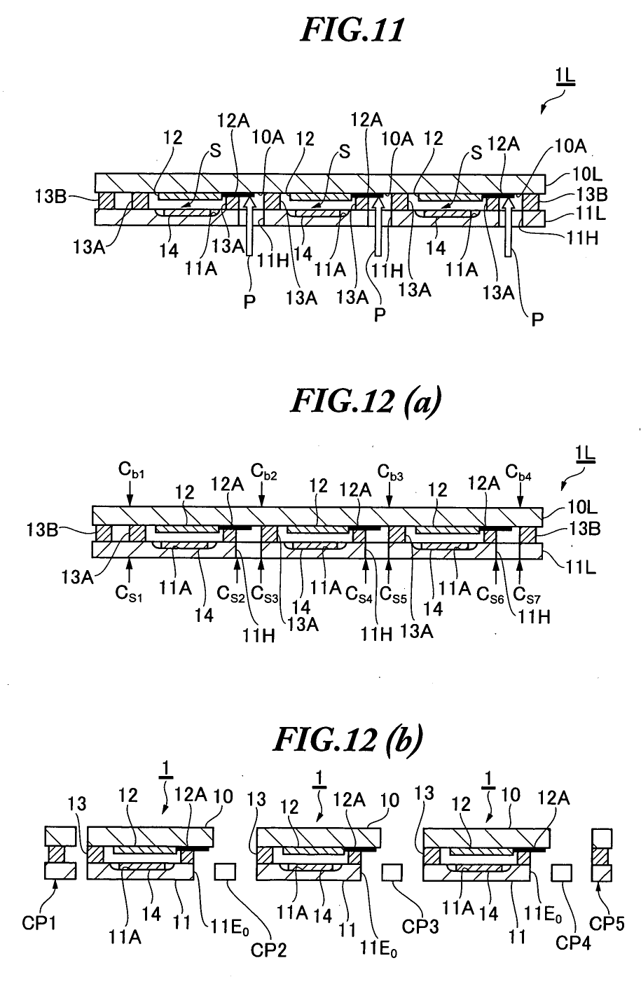

Subsequently, an adhesive agent is applied or printed to the edge portions of the mother support substrate 10L and/or the mother sealing member 11L, also applied or printed to the mother support substrate 10L and/or the mother sealing member 11L to surround each sealing area. Then, the mother support substrate 10L and the mother sealing member 11L are bonded to each other so as to form a mother self-emission panel 1L shown in FIG. 11.

The mother self-emission panel 1L shown in FIG. 11 comprises a mother support substrate 10L having formed thereon a plurality of self-emission sections 12, and a mother sealing member 11L having arranged thereon a plurality of sealing sections 11A corresponding to the plurality of self-emission sections 12. When the mother support substrate 10L and the mother sealing member 11L are bonded together, a plurality of self-emission sections 12 will be arranged to correspond to the plurality of sealing sections 11A, thereby forming a plurality of sealing areas S sealing the self-emission sections 12. If necessary, moisture capturing means (desiccating means) can be provided in the recess portions of the sealing sections 11A.

At this time, adhesive layers 13A and 13B formed by applying or printing an adhesive agent are located between the mother support substrate 10L and the mother sealing member 11L, with the adhesive layers 13A surrounding the sealing areas S and the adhesive layer 13B running along the edge portions of the panel.

Further, regarding the mother self-emission panel 1L, the mother support substrate 10L has a plurality of lead-out areas 10A forming the lead-out wiring portions, 12A extending from the self-emission sections 12 to the outsides of the sealing areas S. Further, the mother sealing member 11L has a plurality of hole processing portions 11H for exposing the lead-out wiring portions 12A.

Namely, regarding the mother self-emission panel 1L, after the mother support substrate 10L and the mother sealing member 11L have been bonded together to form sealing areas S and before they are cut into a plurality of unit panels, the lead-out wiring portions 12A are exposed through the hole processing portions 11H. Therefore, it is possible to insert inspection terminals through the hole processing sections 1H in a manner shown by arrows P, so that the inspection terminals can be connected to the exposed lead-out wiring portions. In this way, it is possible to perform an inspection on the respective self-emission sections 12 prior to the cutting and dividing of the mother self-emission panel 1L. Accordingly, it becomes possible to carry out the inspection step before forming a plurality of separated self-emission panels 1, thus making it possible to integrally handle a plurality of self-emission sections 12. As a result, it is possible to perform an inspection on the respective self-emission sections 12 with an improved efficiency.

FIGS. 12(a) and 12(b) are explanatory views showing the cutting and dividing of the mother self-emission panel 1L (the same elements as those described above are represented by the same reference numerals and the repeated explanation will be partially omitted) As shown in FIG. 12(a), the mother support substrate 10L and the mother sealing member 11L are so treated that they have cutting lines C_{b1}-C_{b4} and Cₛ₁-Cₛ₃. In particular, cutting lines C_{b1}/Cₛ₁, C_{b2}/Cₛ₃, C_{b3}/Cₛ₅, and C_{b4}/Cₛ₇ are set to form the peripheries of the respective self-emission panels 1. On the other hand, cutting lines Cₛ₂, Cₛ₄, and Cₛ₆ are set to form the edges 11E₀ of the respective sealing members 11 facing the lead-out wiring portions 12A. Here, the cutting lines Cₛ₂, Cₛ₃, Cₛ₄, Cₛ₅, Cₛ₆, and Cₛ₇ are set along lines including part of inner edges of the hole processing portions 11H of the mother sealing member 11L.

FIG. 12(b) is an explanatory view showing that a cutting process has been carried out along the aforementioned cutting lines. Actually, such cutting process divides the mother self-emission panel into a plurality of unit panels so as to form a plurality of self-emission panels 1. At this time, a plurality of cutting fragments CP1, CP2, CP3, and CP4 will occur. However, since the cutting fragments CP2, CP3, and CP4 will be open in positions corresponding to the lead-out wiring portions 12A by virtue of the hole processing portions 11H, these fragments will not wound the lead-out wiring portions 12A, thereby making it possible for a final step of the panel manufacturing process to suppress a possibility of making inferior the self-emission panels 1 as low as possible.

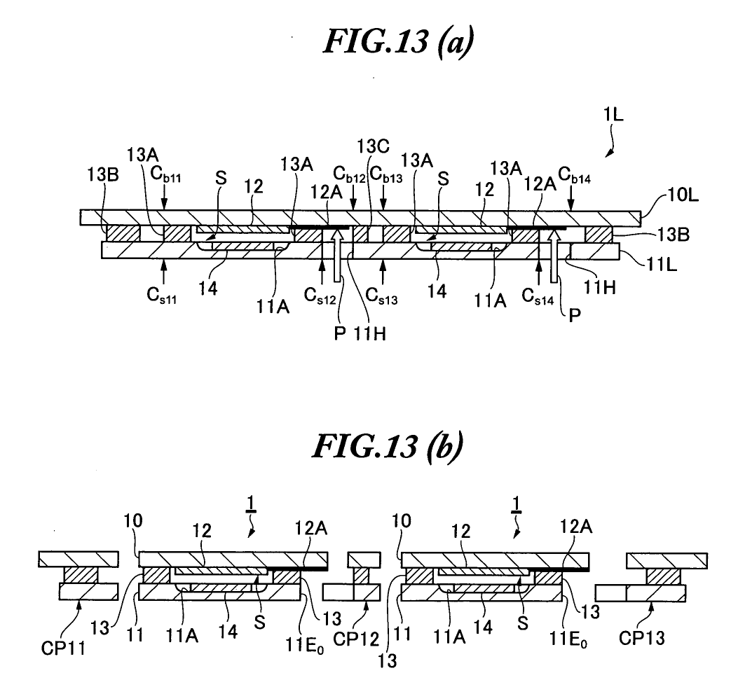

FIGS. 13(a) and 13(b) are explanatory sectional views showing another embodiment of the mother self-emission panel 1L. In detail, FIG. 13(a) is a sectional view of the mother self-emission panel 1L, and FIG. 13(b) is a sectional view showing that the mother self-emission panel 1L (a) has been cut into a plurality of unit panels. Similarly, the same elements as those described above are represented by the same reference numerals and the repeated explanation will be partially omitted. As shown, this mother self-emission panel 1L includes a mother support substrate 10L and a mother sealing member 11L which are bonded to each other by virtue of an adhesive layer 13A surrounding the sealing areas S and another adhesive layer 13B for bonding panel edge portions as well as a further adhesive layer 13C for bonding a panel boundary area.

Further, the mother self-emission panel 1L has set thereon cutting lines C_{b11}-C_{b14} and Cₛ₁₁-Cₛ₁₄. The cutting lines C_{b11}/Cₛ₁₁, C_{b12}, C_{b13}/Cₛ₁₃ and C_{b14} determine the peripheries of the self-emission panels 1, while the cutting lines Cₛ₁₂ and Cₛ₁₄ are set to form edge portions 11E₀ (facing the lead-out wiring portions 12) of the sealing members 11, along lines containing part of inner edges of the hole processing portions 11H of the mother sealing member 11L.

In fact, this embodiment is similar to the above-described embodiment. Namely, before the mother self-emission panel 1L is cut and divided into a plurality of unit panels, inspection terminals are inserted through the hole processing portions 11H in a manner shown by arrows P, thereby connecting the inspection terminals to the lead-out wiring portions 12A, thus making it possible to carry out an inspection step on the mother self-emission panel 1L on which a plurality of self-emission sections 12 have been integrally formed.

Moreover, after the mother self-emission panel 1L has been cut into a plurality of unit panels, cutting fragments CP11-CP13 will occur as shown in FIG. 13(b). At this time, since areas corresponding to the lead-out wiring portions are open due to the hole processing portions 1H, the edges of the cutting fragments CP12 and CP13 will not get into contact with the lead-out wiring portions 12A, thereby making it possible for the lead-out wiring portions to avoid any unfavorable influence during a cutting process. Besides, since the cutting fragments on the mother support substrate 10L side will be combined with the cutting fragments on the mother sealing member 11L side by virtue of the adhesive layer 13C, it is possible to easily perform an operation of removing these cutting fragments.

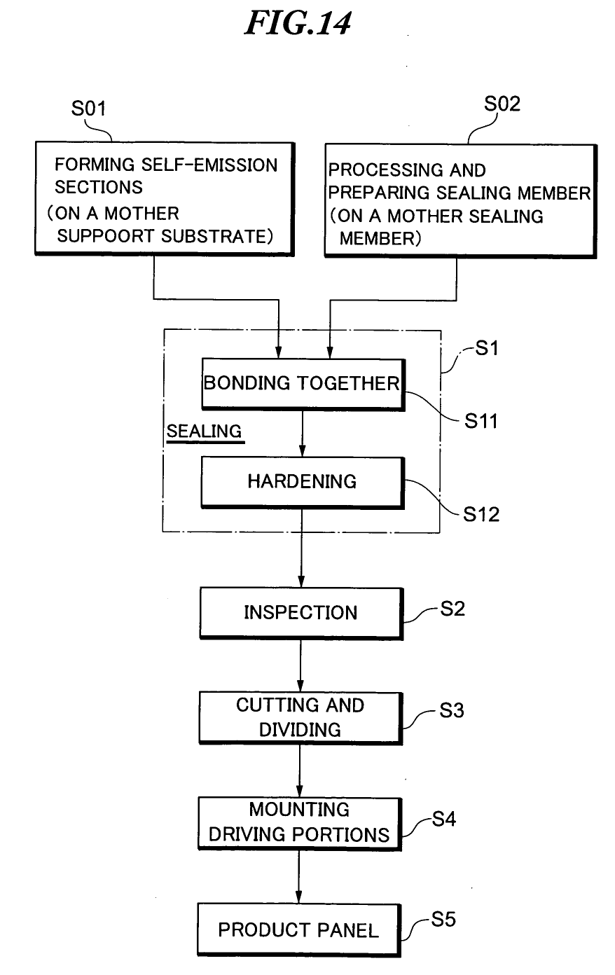

FIG. 14 is an explanatory block diagram showing a process of manufacturing self-emission panels according to an embodiment of the present invention.

At self-emission section forming step S01, a plurality of self-emission sections 12 are formed on a mother support substrate 10L. In practice, various methods can be used to form such self-emission sections 12 according to the type of light emission devices forming the self-emission sections.

As an example of forming self-emission sections consisting of organic EL devices, a mother support substrate 10L made of glass or the like is subjected to a washing treatment, a necessary surface treatment, and a coating treatment (forming a flattening film if the mother support substrate is a TFT substrate). Then, a material (ITO or the like) for forming lower electrodes and lead-out wiring portions is deposited as a thin film on the mother support substrate 10L, using a film formation method such as vapor deposition, sputtering, or the like, followed by patterning the deposited film into a desired pattern by photo lithography or the like. Then, the luminescent areas on the lower electrodes are divided by insulating films, and an organic luminescent functional layer is formed on the luminescent areas, using a wet process including coating method such as spin coating and dipping, a printing method such as screen printing and the ink-jet printing, or a dry process such as vapor deposition and laser transferring. In detail, the organic luminescent functional layer is formed by vapor depositing and thus laminating a hole transporting layer, a luminescent layer, an electron transporting layer. Then, the upper electrodes are formed by a metal film and will act as cathodes, using vapor deposition or sputtering. In this way, organic EL devices are obtained which have a structure formed by interposing an organic luminescent functional layer between upper and lower electrodes.

At a sealing member processing/preparing step S02, the sealing sections 11A mentioned above are formed with respect to the mother sealing member 11L made of glass or the like. If the sealing sections 11A are formed by recess portions, a mask having predetermined openings is placed on the surface of the mother sealing member 11L to carry out a processing such as sandblasting or the like. On the other hand, if the sealing sections 11A are formed by a plan surface, it is not necessary to carry out such a sandblasting. Further, the aforementioned hole processing portions 11H are formed in positions corresponding to the lead-out wiring portions 12A. In this way, it is possible to form the hole processing portions 11H by placing a mask having openings on the surface of the mother sealing member 11L to carry out sandblasting or the like. Besides, if an organic EL panel is to be formed, a moisture capturing agent (desiccating means) 14 can be provided within each sealing section 11A.

A sealing step S1 includes a bonding step S11 and a subsequent curing step S12. The bonding step S11 is to bond together the mother support substrate 10L and the mother sealing member 11L through the afore-mentioned adhesive layers (13A, 13B, 13C). Here, the formation of the adhesive layers by applying or printing an adhesive agent can be performed on the mother support substrate 10L and/or the mother sealing member 11L. Through such bonding step, the self-emission sections 12 on the mother support substrate 10L will be covered by the sealing areas S, while the lead-out wiring portions 12A on the mother support substrate 10L will be exposed from the hole processing portions 11H of the mother sealing member 11L. Then, at the curing step S12, the adhesive layers (13A, 13B, 13C) are hardened by virtue of an ultraviolet irradiation or a heating treatment.

At an inspection step S2, a plurality of self-emission sections 12 are examined by connecting inspection terminals to the lead-out wiring portions 12A exposed from the hole processing portions. As contents of such inspection, it may include the inspections of lighting, chromaticity, and brightness. At this time, it is also possible to connect an inspection terminal to each self-emission section 12 so as to inspect each self-emission section. Alternatively, it is also possible to prepare a plurality of inspection terminals corresponding to the lead-out wiring portions 12A of a plurality of self-emission sections 12, thereby connecting these inspection terminals and examining the plurality of self-emission sections 12 at the same time. Anyway, each of the above cases is easier to handle than a case in which each respective panels 1 are handled after a mother self-emission panel is cut into unit panels, thereby making it possible to effectively perform the inspection operation.

At cutting/dividing step S3, cutting is carried out along the cutting lines described above, so that the mother support substrate 10L and the mother sealing member 11L are cut into a plurality of unit panels each having a sealing area S and a lead-out wiring portion 12A.

At this time, as described above, the cutting/dividing step is carried out along the cutting lines containing part of inner edges of the hole processing portions 11H of the mother sealing member 11L. In this way, even if cutting fragments occur, edges of the fragments will not get into contact with the lead-out wiring portions 12A due to the presence of the hole processing portions 11H. Therefore, it becomes possible to avoid some troubles such as wire breakage in the lead-out wiring portions 12A during the cutting/dividing step at the end of the manufacturing process.

Subsequently, driving portions (IC chips and flexible substrates) are mounted on to the respective self-emission panels 1 obtained at the cutting/dividing step S3, thereby completing a driving portion mounting step S4, thus completing the manufacturing of product panels (S5).

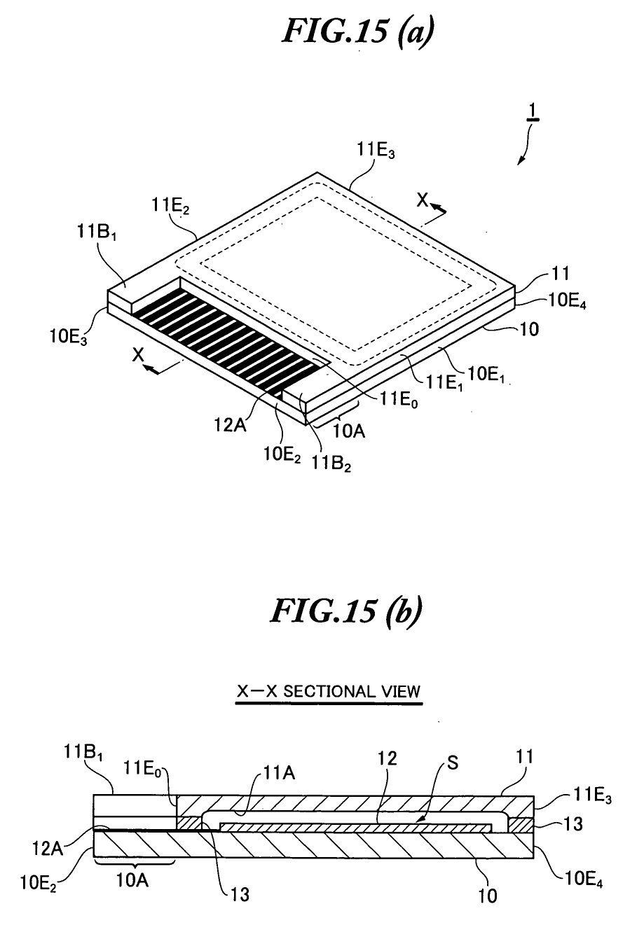

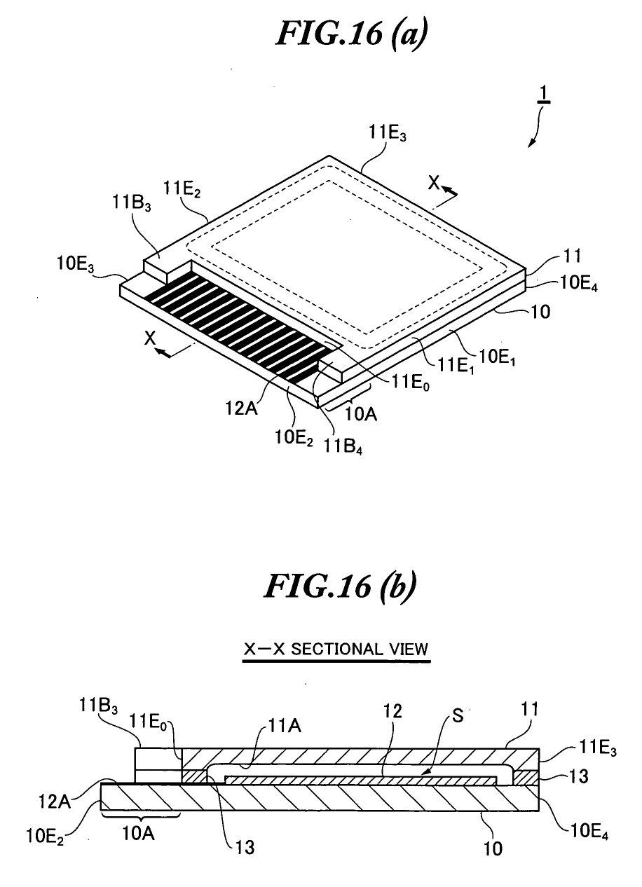

FIGS. 15 and 16 are explanatory views showing a self-emission panel formed according to another embodiment of the present invention. FIGS. 15(a) and 16(a) are perspective views and FIGS. 8(b) and 9(b) are sectional views taken along X-X lines in FIGS. 15(a) and 16(a). Similarly, the same elements as those of the embodiment shown in FIGS. 9(a) and 9(b) are represented by the same reference numerals and the repeated explanation will be partially omitted. Actually, in this embodiment, a self-emission panel 1 has the same basic structure as those in other embodiments. Namely, the self-emission panel 1 is obtained by forming a self-emission section 12 on a support substrate 10, disposing the self-emission section 12 in a sealing area S formed by bonding together the support substrate 10 and the sealing member 11 through an adhesive layer 13, and forming a lead-out wiring portion 12A extending from the self-emission section 12 to the outside of the sealing area S on the lead-out area 10A of the support substrate 10. On the other hand, this embodiment is characterized by providing reinforcement portions 11B₁ to 11B₄ extending from the edge 11E₀ over to the lead-out area 10A. These reinforcement portions 11B₁ to 11B₄ are provided for reducing a stress concentration on the support substrate 10 under the edge 11E₀, reinforcing a maximum bending moment on the lead-out area 10A of the support substrate 10 when supporting things only on one side thereof. In this way, it is possible to prevent the support substrate 10 from being broken at the base of the lead-out area 10A.

The reinforcement portions 11B₁ to 11B₄, as shown in FIGS. 15(a) and 15(b), may be reinforcement portions 11B₁ and 11B₂ located on both sides of the lead-out wiring portion 12A and corresponding to the length of the lead-out area 10A, or allowed to be reinforcement portions 11B₃ and 11B₄ located on both sides of the lead-out wiring portion 12A but shorter than the length of the lead-out area 10A. Moreover, as mentioned above, when providing the reinforcement portions 11B₁, 11B₂, 11B₃, and 11B₄ on both sides of the lead-out wiring portion 12A, it is not necessary for the reinforcement portions to be formed symmetrically, but they are allowed to have different widths or lengths. In addition, it is also possible to omit one of the left and right reinforcement portions so that a reinforcement portion is provided only on one side of the lead-out wiring portion 12A.

In this way, since the width of each hole processing portion 11H of the above-described mother sealing member 11L is made narrower than the width of each cut/separated unit sealing member 11, the above reinforcement sections 11B₁ to 11B₄ can be formed on one or both sides of each hole processing portion 11H.

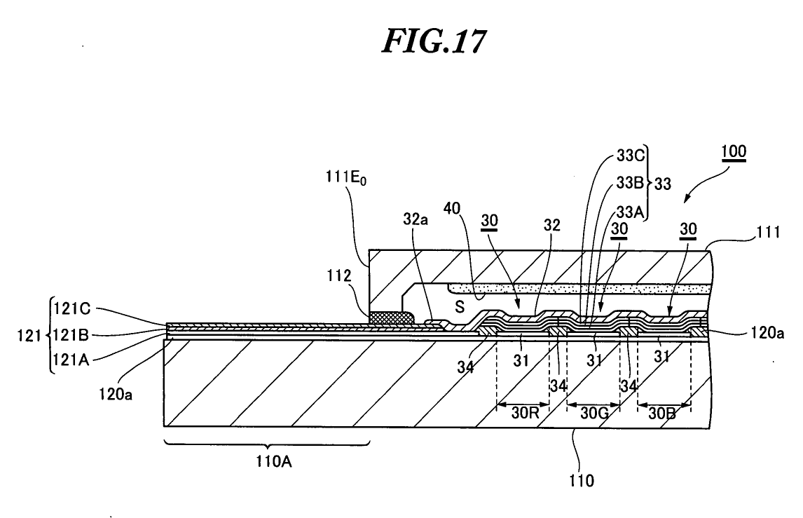

In the following, with reference to FIG. 17, description will be given to explain an organic EL panel serving as an example of the foregoing self-emission panel 1.

As shown, an organic EL panel 100 is formed by interposing an organic layer 33 containing an organic luminescent layer between first electrodes 31 (lower electrodes) on one hand and second electrodes 32 (upper electrodes) on the other, thereby forming a plurality of organic EL devices 30 on the support substrate 110. In an example shown in FIG. 10, a silicone coating layer 120a is formed on the support substrate 110, and a plurality of first electrodes 31 consisting of transparent electrode material such as ITO and serving as anodes are formed on the silicon coating layer 120a. Further, second electrodes 32 consisting of a metal such as Al and serving as cathodes are formed over the first electrodes 31, thereby forming a bottom emission type panel capable of emitting light from the support substrate 110 side. Moreover, the panel also contains an organic layer 33 including a positive hole transporting layer 33A, a luminescent layer 33B, and an electron transporting layer 33C. Then, the support substrate 110 and a sealing member 111 are bonded together through an adhesive layer 112, thereby forming a sealing area S, thus forming a self-emission section consisting of organic EL devices 30 within the sealing area S.

A self-emission section consisting of organic EL devices 30, as shown in the drawing, is so formed that its first electrodes 31 are divided by insulating strips 34, thereby forming a plurality of unit display areas (30R, 30G, 30B) by virtue of the respective organic EL devices 30 located under the divided first electrodes 31. Further, desiccating means 40 is attached to the inner surface of the sealing member 111 forming the sealing area S, thereby preventing a deterioration of the organic EL devices which is possibly caused due to moisture.

Moreover, on the lead-out area 110A formed along the edge of the support substrate 110 there is formed a first electrode layer 121A using the same material and the same step as forming the first electrodes 31, which is separated from the first electrodes 31 by the insulating strips 34. Further, on the lead-out portion of the first electrode layer 21A there is formed a second electrode layer 21B forming a low-resistant wiring portion containing a silver alloy or the like. In addition, if necessary, a protection coating layer 121C consisting of IZO or the like is formed on the second electrode layer 21B. In this way, a lead-out wiring portion 121 can be formed which consists of the first electrode layer 121A, the second electrode layer 121B, and the protection coating 121C. Then, an edge portion 32a of each second electrode 32 is connected to the lead-out wiring portion 121 at edge portion of the sealing area S.

Here, although the lead-out wiring portion of each first electrode 31 is not shown in the drawing, such lead-out wiring portion can be formed by extending each first electrode 31 and leading the same out of the sealing area S. Actually, such lead-out wiring portion can also be formed into an electrode layer forming a low resistant wiring portion containing a silver alloy or the like in a manner similar to an example associated with the above-described second electrode 32.

Then, edges 111E₀ facing the lead-out wiring portions 121 of the sealing member 111 are formed by hole processing edges formed before bonding together the support substrate 110 and the sealing member 111.

Next, description will be given in more detail to explain the details of the aforementioned organic EL panel 100.

a. Electrodes

Either the first electrodes 31 or the second electrodes 32 are set as cathode side, while the opposite side is set as anode side. The anode side is formed by a material having a higher work function than the cathode side, using a transparent conductive film which may be a metal film such as chromium (Cr), molybdenum (Mo), nickel (nickel), and platinum (Pt), or a metal oxide film such as ITO and IZO. In contrast, the cathode side is formed by a material having a lower work function than the anode side, using a metal having a low work function, which may be an alkali metal (such as Li, Na, K, Rb, and Cs), an alkaline earth metal (such as Be, Mg, Ca, Sr, and Ba), a rare earth metal, a compound or an alloy containing two or more of the above elements, or an amorphous semiconductor such as a doped polyaniline and a doped polyphenylene vinylene, or an oxide such as Cr₂O₃, NiO, and Mn₂O₅. Moreover, when the first electrodes 31 and the second electrodes 32 are all formed by transparent materials, it is allowed to provide a reflection film on one electrode side opposite to the light emission side.

The lead-out wiring portion (the lead-out wiring portion 121 and the lead-out wiring portion of the first electrodes 31, as shown in the figure) are connected with drive circuit parts driving the organic EL panel 100 or connected with a flexible wiring board. However, it is preferable for these lead-out wiring portions to be formed as having a low resistance as possible. Namely, the lead-out wiring portions can be formed by laminating low resistant metal electrode layers which may be Ag-alloy, Cr, Al, or the like. Alternatively, they may be formed by single one electrode of low resistant metal.

b. Organic Layer

Although the organic layer 33 comprises one or more layers of organic compound materials including at least one organic luminescent layer, its laminated structure can be in any desired arrangement. Usually, in the case of a low molecule organic EL material, as shown in FIG. 14, there is a laminated structure including, from the anode side towards the cathode side, a hole transporting layer 33A, a luminescent layer 33B, and an electron transporting layer 33C. Each of the hole transporting layer 33A, the luminescent layer 33B, and the electron transporting layer 33C can be in a single-layer or a multi-layered structure. Moreover, it is also possible to dispense with the hole transporting layer 33A and/or the electron transporting layer 33C. On the other hand, if necessary, it is allowed to insert other organic layers including a hole injection layer, and an electron injection layer. Here, the hole transporting layer 33A, the luminescent layer 33B, and the electron transporting layer 33C can be formed by any conventional materials (it is allowed to use either a high molecular material or a low molecular material).

Regarding to a luminescent material for forming the luminescent layer 33B, it is allowed to make use of a luminescence (fluorescence) obtained when the material returns from a singlet excited state to a base state or a luminescence (phosphorescence) obtained when it returns from a triplet excited state to a base state.

c. Sealing Member

In the organic EL panel 100, the covering member for tightly covering organic EL devices 30 may be a plate-like member made of glass or plastic. Here, the sealing cover may be apiece of material having a recess portion (a one-step recess or a two-step recess) formed by pressing, etching, or blasting. Alternatively, the sealing cover may be formed by using a flat glass plate capable of forming a sealing area S between the flat glass plate and the support substrate 110 by virtue of a spacer made of glass (or plastic)

d. Adhesive Agent

An adhesive agent forming the adhesive layer 112 may be a thermal-setting type, a chemical-setting type (2-liquid mixture), or a light (ultraviolet) setting type, which can be formed by an acryl resin, an epoxy resin, a polyester, a polyolefine. Particularly, it is preferable to use an ultraviolet-setting epoxy resin adhesive agent which is quick to solidify without a heating treatment.

e. Desiccating Means

Desiccating means 40 may be a physical desiccating agent such as zeolite, silica gel, carbon, and carbon nanotube; a chemical desiccating agent such as alkali metal oxide, metal halogenide, peroxide chlorine; a desiccating-agent formed by dissolving an organic metallic complex in a petroleum system solvent such as toluene, xylene, an aliphatic organic solvent and the like; and a desiccating agent formed by dispersing desiccating particles in a transparent binder such as polyethylene, polyisoprene, polyvinyl thinnate.

f. Various Types of Organic EL Panels

The organic EL panel 100 of the present invention can have various types without departing from the scope of the invention. For example, the light emission type of organic EL devices 30 can be bottom emission type which emit light from the substrate 110 side, or top emission type which emit light from the sealing member 111 side (at this time, it is necessary for the sealing member 111 to be made of a transparent material and to dispose the desiccating means 40). Moreover, an organic EL display panel 100 may be a single color display or a multi-color display. In order to form a multi-color display, it is possible to adopt a discriminated painting method or a method in which a single color (white or blue) luminescent layer is combined with a color conversion layer formed by a color filter or a fluorescent material (CF manner, CCM manner), a photograph breeching method which realizes a multiple light emission by emitting an electromagnetic wave or the like to the light emission area of a single color luminescent layer, a SOLED (transparent Stacked OLED) method in which two or more colors of unit display areas are laminated to form one unit display area, or a laser transfer method in which low molecular organic material having different luminescent colors are deposited in advance on to different films and then transferred to one substrate by virtue of thermal transfer using a laser. Besides, although the accompanying drawings show only a passive driving manner, it is also possible to adopt an active driving manner by adopting TFT substrate serving as support substrate 110, forming thereon a flattening layer and further forming the first electrodes 31 on the flattening layer.

As described above, using the self-emission panel and the method of manufacturing the same or the self-emission panel sealing member according to the above-described embodiments of the present invention, with respect to a process of forming respective self-emission panels 1 by cutting a mother self-emission panel into small portions, it possible to prevent a damage in the lead-out wiring portions and thus improving the yield of production. Further, with respect to a process of forming respective self-emission panels by cutting a mother self-emission panel into small portions, it is possible to ensure an improved efficiency for an inspection step and thus ensure an improved productivity.

While there has been described what are at present considered to be preferred embodiments of the present invention, it will be understood that various modifications may be made thereto, and it is intended that the appended claims cover all such modifications as fall within the true spirit and scope of the invention.

What is claimed is:

1. An electro-optical panel including a sealing area having an electro-optical functional section between a pair of mutually facing members, wherein
one of the mutually facing members comprises a support substrate having a lead-out area containing an area for forming lead-out wiring extending from the sealing area and for connecting or mounting drive means to the lead-out wiring,
the other of the mutually facing members has protruding reinforcement section(s) protruding from the sealing area on to the lead-out area.

2. The electro-optical panel according to claim 1, wherein the other of the mutually facing members forms a support structure in which the sealing area and the protruding reinforcement section(s) are contained within the same plane.

3. The electro-optical panel according to claim 1, wherein the protruding reinforcement section(s) are formed on the lead-out area except an area connecting or mounting the drive means.

4. The electro-optical panel according to claim 1, wherein the protruding reinforcement sections are located in a plurality of positions along one side, and the protruding lengths of the respective protruding reinforcement sections are equal to one another.

5. The electro-optical panel according to claim 1, wherein the protruding reinforcement sections are located in a plurality of positions along one side, the protruding length of at least one protruding reinforcement section is different from that of other protruding reinforcement sections.

6. The electro-optical panel according to claim 1, wherein the protruding reinforcement section(s) are bonded and thus fixed in the lead-out area.

7. The electro-optical panel according to claim 1, wherein one or both of the mutually facing members are made of transparent material.

8. The electro-optical panel according to claim 1, wherein said electro-optical functional section is formed by organic EL device(s) consisting of one or more organic luminescence functional layers.

9. A sealing member forming a sealing area having an electro-optical functional section between the sealing member and a support substrate,
wherein the sealing member has protruding reinforcement section(s) extending from the sealing area,
wherein the protruding reinforcement section(s) are formed on the support substrate and arranged in a lead-out area containing an area for forming lead-out wiring extending from the sealing area and for connecting or mounting the drive means to the lead-out wiring.

10. The sealing member according to claim 9, wherein notches are formed which open areas adjacent to the protruding reinforcement sections and connect or mount the drive means.

11. The sealing member according to claim 10, wherein said sealing member is formed by cutting one piece of plate having a plurality of sealing areas into a plurality of sealing members each containing a sealing area, the notches are formed by openings formed on said one piece of plate.

12. A method of manufacturing an electro-optical panel including a sealing area having an electro-optical functional section between a pair of mutually facing members, wherein
one of the mutually facing members comprises a support substrate having a lead-out area containing an area for forming lead-out wiring extending from the sealing area and for connecting or mounting drive means to the lead-out wiring,
the other of the mutually facing members has protruding reinforcement section(s) protruding from the sealing area on to the lead-out area,
wherein
an adhesive layer surrounding the sealing area is formed on one or both of the mutually facing members, and the pair of said mutually facing members are bonded together through the adhesive layer.

13. The method according to claim 12, wherein said adhesive layer is also formed on the protruding reinforcement section(s).

14. A self-emission panel in which a self-emission section is formed on a support substrate and disposed within a sealing area formed by bonding together the support substrate and a sealing member, a lead-out wiring portion extending from the self-emission section to the outside of the sealing area is formed on a lead-out area in an edge of the support substrate,
wherein the sealing member's edge facing the lead-out wiring portion is a hole processing edge formed before the support substrate and the sealing member are bonded together.

15. The self-emission panel according to claim 14,
wherein the support substrate is one of substrates formed by cutting a mother support substrate having formed thereon a plurality of self-emission sections,
wherein the sealing member is one of sealing members formed by cutting a mother sealing member having arranged there on a plurality of sealing sections corresponding to the plurality of self-emission sections,
wherein the hole processing edge is part of an inner edge of a hole processing portion formed on the mother sealing member.

16. A self-emission panel comprising:
a mother support substrate having formed thereon a plurality of self-emission sections;
a mother sealing member having arranged thereon a plurality of sealing sections corresponding to the plurality of self-emission sections, and
sealing areas formed by bonding together the mother support substrate and the mother sealing member for sealing the plurality of self-emission sections, with said plurality of self-emission sections corresponding to said plurality of sealing sections,
wherein the mother support substrate includes lead-out areas having formed thereon lead-out wiring portions extending from the plurality of self-emission sections to the outsides of the sealing areas,
wherein the mother sealing member has hole processing portions for exposing the lead-out wiring portions.

17. A method of manufacturing self-emission panels, said method comprising the steps of:
forming a plurality of self-emission sections on a mother support substrate;
forming on a mother sealing member hole processing potions corresponding to lead-out wiring portions of the plurality of self-emission sections;
bonding together the mother support substrate and the mother sealing member to expose the lead-out wiring portions from the hole processing portions, and sealing the plurality of self-emission sections within sealing areas corresponding to sealing sections of the mother sealing member;
examining the plurality of self-emission sections by connecting inspection terminals to the lead-out wiring portions exposed from the hole processing portions;
cutting and dividing the mother support substrate and the mother sealing member into unit panels having said sealing areas and said lead-out wiring portions.

18. The method according to claim 17, wherein said cutting and dividing are carried out along cutting lines containing part of inner edges of the hole processing portions.

19. A self-emission panel sealing member for sealing a plurality of self-emission sections formed on a mother support substrate by being bonded to the mother support substrate,
wherein said sealing member has a plurality of sealing sections corresponding to the plurality of self-emission sections, and a plurality of hole processing portions corresponding to lead-out wiring portions of the plurality of self-emission sections.
